(19) United States
(12) Patent Application Publication
(10) Pub. No.: US 2025/0160081 A1
(43) Pub. Date: May 15, 2025

(54) DISPLAY DEVICE AND METHOD OF FABRICATING THE SAME

(71) Applicant: LG Display Co., Ltd., Seoul (KR)

(72) Inventors: Hyuk JI, Paju-si (KR); Sang Gil KIM, Paju-si (KR)

(21) Appl. No.: 18/830,334

(22) Filed: Sep. 10, 2024

(30) Foreign Application Priority Data
Nov. 15, 2023 (KR) 10-2023-0158177

(51) Int. Cl. H01L 33/62; H01L 25/16; H01L 33/48

(52) U.S. Cl. CPC H10H 20/857; H01L 25/167; H10H 20/8506; H10H 20/0364

(57) ABSTRACT

An embodiment discloses a display device including an insulating layer disposed on a substrate, first electrodes and contact electrodes disposed on the insulating layer, a plurality of light emitting devices disposed on the first electrodes, a second electrode disposed on the light emitting devices; and a passivation layer covering the first electrode, and a first opening hole exposing a portion of the upper surface of the first electrode.

### CROSS-REFERENCE TO RELATED APPLICATION

This application claims priority to and the benefit of Korean Patent Application No. 10-2023-0158177, filed on Nov. 15, 2023, the disclosure of which is incorporated herein by reference in its entirety.

### BACKGROUND

### Technical Field

An embodiment relates to a display device using an inorganic light-emitting diode as a light source and a method of fabricating the same.

### Description of the Related Art

An electroluminescent display device includes an organic light-emitting display device in which an organic light-emitting diode (OLED) is disposed and an inorganic light-emitting display device (hereinafter referred to as “LED display device”) in which an inorganic light-emitting diode (hereinafter referred to as “LED”) is disposed.

The electroluminescent display device displays images using self-luminous elements, and thus does not require a separate light source, for example, a backlight unit, and can be implemented in various thin forms.

In the organic light-emitting display device, since an oxidation phenomenon between an organic light-emitting layer and an electrode can occur due to penetration of moisture and oxygen, a design for preventing penetration of oxygen and moisture is required.

Recently, as an example of the inorganic light-emitting display device, a micro LED display device in which micro LEDs are disposed in pixels has been attracting attention as a next-generation display device. The micro LED may be an inorganic LED with a size of 100 μm or less. Micro LEDs are fabricated through a separate semiconductor process and transferred to pixel positions on a display panel substrate of the display device, and can be disposed in each sub-pixel for each color.

### BRIEF SUMMARY

The present disclosure provides a display device in which a metal layer having a low adhesive strength with a first optical layer and a second optical layer is prevented from being in contact with the first optical layer and the second optical layer in the remaining region except for a region overlapping light-emitting elements, and thus an adhesive strength of the first optical layer and the second optical layer to an insulating layer is increased and contact resistance between a circuit component and a pad portion signal line is reduced in a pad portion.

The technical problems to be solved by the present disclosure are not limited to the above-mentioned technical problems, and other technical problems which are not mentioned will be clearly understood by those skilled in the art from the following description.

The technical problem is solved by a display device including: an insulating layer disposed on a substrate; a bank pattern disposed on the insulating layer; a first electrode including a plurality of metal layers disposed on the bank pattern; a first metal layer disposed on the first electrode; a solder pattern disposed on the first metal layer; a light-emitting element disposed on the solder pattern; and a second electrode disposed on the light-emitting element, wherein the first metal layer is disposed only in a region overlapping the light-emitting element.

According to the present disclosure, a first metal layer is formed only in a region overlapping a light-emitting element. Accordingly, when the first metal layer includes indium tin oxide (ITO), since an adhesive strength with a first optical layer and/or a second optical layer is reduced, a lifting phenomenon of the first optical layer and/or the second optical layer on the first metal layer can be prevented. Further, in a pad portion, when a circuit component is attached to a portion of signal lines through an adhesive containing conductive balls such as an anisotropic conductive film (ACF), a problem in that contact resistance with the first metal layer increases can be prevented.

In addition, when wet etching is performed to form openings in the first metal layer including indium tin oxide (ITO) disposed on a bank pattern, a problem in that crystallized indium tin oxide (ITO) is not etched can be prevented.

The various and helpful advantages and effects of the present disclosure are not limited to the above-described content, and other effects which are not mentioned will be clearly understood by those skilled in the art from the following description.

### BRIEF DESCRIPTION OF THE SEVERAL VIEWS OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a view illustrating a display device according to one embodiment of the present disclosure;

FIG. 2 is an enlarged view illustrating region A in FIG. 1;

FIG. 3 is a view illustrating a partial region of a pixel;

FIG. 4 is a cross-sectional view taken along line I-I′ in FIG. 3;

FIG. 5 is a cross-sectional view taken along line II-II′ in FIG. 3;

FIG. 6 is a cross-sectional view taken along line III-III′ in FIG. 3;

FIG. 7 is a cross-sectional view illustrating an example in which a main light-emitting element and a sub light-emitting element are electrically connected to a pixel driving circuit;

FIG. 8 is a view illustrating a display device according to another embodiment of the present disclosure;

FIG. 9 is a cross-sectional view taken along line IV-IV′ in FIG. 8;

FIG. 10A is a view illustrating a display device according to another embodiment of the present disclosure;

FIG. 10B is an enlarged view of region B in FIG. 10A;

FIG. 11 is a cross-sectional view taken along line A-A′ in FIG. 10B; and

FIGS. 12A to 12G are views illustrating a process of fabricating a display device according to one embodiment of the present disclosure.

### DETAILED DESCRIPTION

Advantages and features of the present disclosure, and methods of achieving them will become apparent with reference to the following embodiments, which are described in detail, in conjunction with the accompanying drawings. The present disclosure is not limited to the embodiments to be described below and may be implemented in various different forms, the embodiments are only provided to completely disclose the present disclosure and completely convey the scope of the present disclosure to those skilled in the art, and the present disclosure is defined only by the scope of the claims.

Since the shapes, sizes, dimensions (e.g., length, width, height, thickness, radius, diameter, area, etc.), proportions, angles, numbers, and the like disclosed in the drawings for describing the embodiments of the present disclosure are only exemplary, the present disclosure is not limited to the items shown in the drawings.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Throughout the disclosure, the same reference numerals refer to substantially the same components. Further, in describing the present disclosure, when it is determined that a detailed description of related known technology may unnecessarily obscure the gist of the present disclosure, the detailed description thereof will be omitted.

When ‘providing,’ ‘including,’ ‘having,’ ‘consisting of,’ and the like mentioned in the present disclosure are used, other parts may be added unless ‘only’ is used. A component expressed in a singular form may also be interpreted as a plural form unless explicitly stated otherwise.

In interpreting the components, it should be understood that an error range is included even when there is no separate explicit description.

When a positional relationship and an interconnection relationship between two components such as ‘on,’ ‘at an upper portion,’ ‘at a lower portion,’ ‘next to,’ ‘connect or couple,’ ‘crossing or intersecting,’ or the like are described, one or more other components may be interposed between the components unless there is a mention such as ‘immediately’ or ‘directly.’

When a temporal relationship is described as ‘after,’ in succession to,′ ‘and then,’ ‘before,’ or the like, the temporal relationship may not be continuous on a time axis unless ‘immediately’ or ‘directly’ is used.

First, second, and the like may be used in front of the names of components to distinguish the components, but functions or structures are not limited by these ordinal numbers or component names. For convenience of description, the ordinal numbers in front of the name of the same components may be different between embodiments.

The following embodiments may be partially or fully combined with each other, and technically, various types of interconnections and driving are possible. The embodiments may be implemented independently of each other or may be implemented together in a related relationship.

Hereinafter, various embodiments of the present disclosure will be described in detail with reference to the accompanying drawings.

A display device according to one embodiment of the present disclosure includes a display region where an image is displayed or a display panel on which a screen is disposed, and a pixel driving circuit which drives pixels of the display panel. The display region includes a pixel region where the pixels are disposed. The pixel region includes a plurality of light-emitting regions. A light-emitting element is disposed in each of the light-emitting regions. The pixel driving circuit may be built into the display panel.

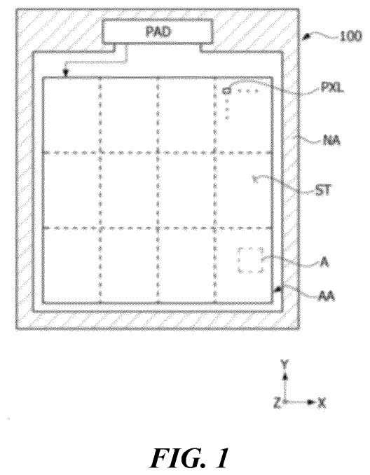

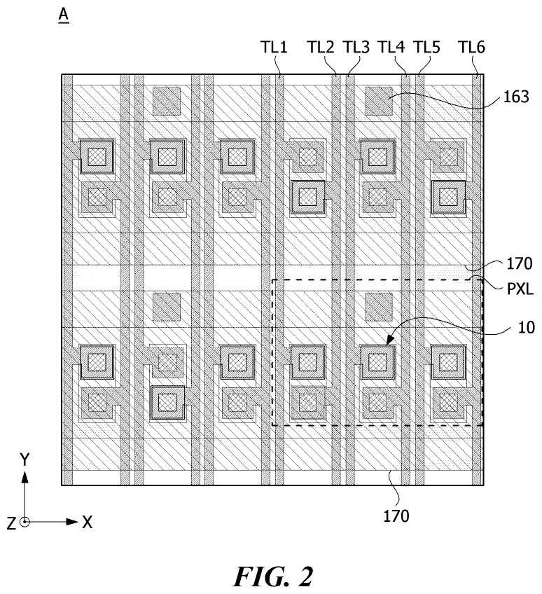

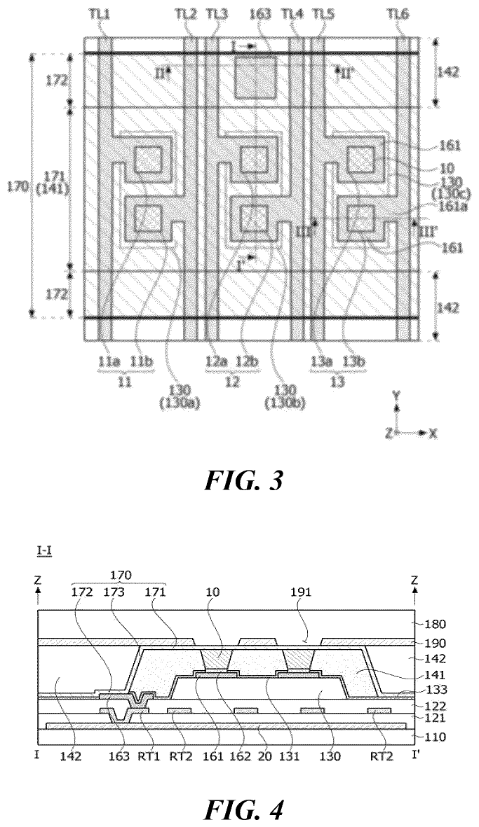

FIG. 1 is a view illustrating a display device according to one embodiment of the present disclosure. FIG. 2 is an enlarged view illustrating region A in FIG. 1. FIG. 3 is a view illustrating a partial region of a pixel.

Referring to FIGS. 1 and 2, a display device 100 according to one embodiment of the present disclosure includes a display panel where an input image is visually reproduced. The display panel may include a display region AA where an image is displayed and a non-display region NA where the image is not displayed. In the non-display region NA, various lines and driving circuits may be mounted, and a pad portion PAD to which an integrated circuit, a printed circuit, and the like are connected may be disposed. Here, the display panel may be a panel with a rectangular structure having a width in an X-axis direction, a length in a Y-axis direction, and a thickness in a Z-axis direction. In this case, the width and length of the display panel may be set to various design values according to application fields of the display device. The X-axis direction may mean a width direction, row direction, or lateral direction, the Y-axis direction may mean a length direction, column direction, or longitudinal direction, and the Z-axis direction may mean a vertical direction or thickness direction. Further, the X-axis direction, the Y-axis direction, and the Z-axis direction may be perpendicular to each other, but may also mean different directions not perpendicular to each other. Accordingly, each of the X-axis direction, the Y-axis direction, and the Z-axis direction may be described as one of a first direction, a second direction, and a third direction. Further, a plane extending in the X-axis direction and the Y-axis direction may mean a horizontal plane.

A plurality of light-emitting elements 10 disposed in the display region AA and forming pixels PXL may be micro-sized inorganic light-emitting elements. The inorganic light-emitting elements may be grown on a silicon wafer and then attached to the display panel through a transfer process.

A transfer process of the light-emitting elements 10 may be performed for each previously divided region. In FIG. 1, an example in which the display region AA is divided into nine transfer regions ST is described, but the sizes or number of divided transfer regions are not limited thereto. The transfer process may be performed sequentially or simultaneously on a first transfer region ST to a ninth transfer region ST. A blue light-emitting element 10, a green light-emitting element 10, and a red light-emitting element 10 may be sequentially transferred to each transfer region ST.

In the non-display region NA, data driving circuits or gate driving circuits may be disposed, and lines to which control signals for controlling these driving circuits are supplied may be disposed. Here, the control signals may include various timing signals including a clock signal, an input data enable signal, and a synchronization signal and may be received through the pad portion PAD.

The pixels PXL may be driven by the pixel driving circuit. The pixel driving circuit may receive a driving voltage, an image signal (digital signal), a synchronization signal synchronized with the image signal, and the like and output an anode voltage and a cathode voltage of the light-emitting element 10 to drive a plurality of pixels. The driving voltage may be a high-potential voltage EVDD. The cathode voltage may be a low-potential voltage EVSS applied to the pixels in common. The anode voltage may be a voltage corresponding to a pixel data value of the image signal. The pixel driving circuit may be disposed in the non-display region NA or under the display region AA.

Each pixel PXL may include a plurality of sub-pixels having different colors. For example, each of the plurality of pixels may include a red sub-pixel where the light-emitting element 10 which emits red wavelength light is disposed, a green sub-pixel where the light-emitting element 10 which emits green wavelength light is disposed, and a blue sub-pixel where the light-emitting element 10 which emits blue wavelength light is disposed. The plurality of pixels may further include a white pixel

Referring to FIGS. 2 and 3, the plurality of pixels PXL may be continuously disposed in a first direction (X-axis direction) and a second direction (Y-axis direction). A plurality of sub-pixels of the same color may be disposed in the pixel of the display region AA. For example, each of the plurality of pixels may include a first red sub-pixel where a 1-1 light-emitting element 11a which emits red wavelength light is disposed, a second red sub-pixel where a 1-2 light-emitting element 11b which emits red wavelength light is disposed, a first green sub-pixel where a 2-1 light-emitting element 12a which emits green wavelength light is disposed, a second green sub-pixel where a 2-2 light-emitting element 12b which emits green wavelength light is disposed, a first blue sub-pixel where a 3-1 light-emitting element 13a which emits blue wavelength light is disposed, and a second blue sub-pixel where a 3-2 light-emitting element 13b which emits blue wavelength light is disposed. The 1-1 light-emitting element 11a, the 2-1 light-emitting element 12a, and the 3-1 light-emitting element 13a may be interpreted as main light-emitting elements. The 1-2 light-emitting element 11b, the 2-2 light-emitting element 12b, and the 3-2 light-emitting element 13b may be interpreted as sub light-emitting elements.

One sub-pixel may include at least one or more light-emitting elements, and thus the brightness of the sub-pixel may be adjusted by increasing the brightness of the other light-emitting elements when one light-emitting element becomes defective. However, the present disclosure is not necessarily limited thereto, and one sub-pixel may include only one light-emitting element.

A plurality of first electrodes 161 may be respectively disposed under the light-emitting elements 10 and may be selectively connected to a plurality of signal lines TL1 to TL6 through a connection portion 161a. A high-potential voltage may be applied to the pixel driving circuit through the signal lines TL1 to TL6. The signal lines TL1 to TL6 and the first electrodes 161 may be formed as an integrated electrode pattern in an electrode patterning process.

For example, a first signal line TL1 may be connected to an anode electrode of the first red sub-pixel, and a second signal line TL2 may be connected to an anode electrode of the second red sub-pixel. A third signal line TL3 may be connected to an anode electrode of the first green sub-pixel, and a fourth signal line TL4 may be connected to an anode electrode of the second green sub-pixel. A fifth signal line TL5 may be connected to an anode electrode of the first blue sub-pixel, and a sixth signal line TL6 may be connected to an anode electrode of the second blue sub-pixel. When one sub-pixel includes only one light-emitting element, the number of signal lines TL may be reduced by half.

The second electrode 170 may be a cathode electrode that is disposed in each row and applies a cathode voltage to the light-emitting elements 10 continuously disposed in the first direction (the X-axis direction). A plurality of second electrodes 170 may be disposed to be spaced apart from each other in the second direction (the Y-axis direction). The plurality of second electrodes 170 may be connected to the cathode voltage through a contact electrode 163. Each of the plurality of second electrodes 170 may be electrically connected to the contact electrode 163. However, the present disclosure is not necessarily limited thereto, and the second electrode 170 may not be divided into the plurality of second electrodes 170 and may be configured as one electrode layer and function as a common electrode.

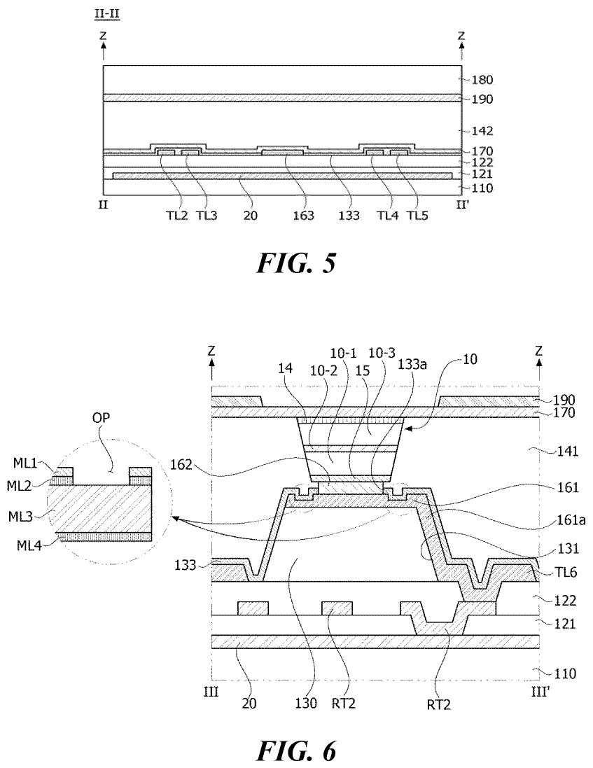

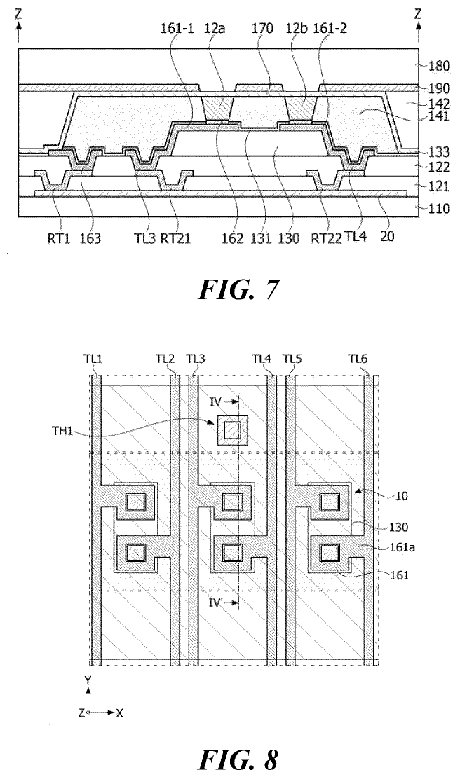

FIG. 4 is a cross-sectional view taken along line I-I′ in FIG. 3. FIG. 5 is a cross-sectional view taken along line II-II′ in FIG. 3. FIG. 6 is a cross-sectional view taken along line III-III′ in FIG. 3. FIG. 7 is a cross-sectional view illustrating an example in which two light-emitting elements are connected to the pixel driving circuit.

Referring to FIGS. 3 to 5, the display device according to the embodiment includes the plurality of first electrodes 161 and the contact electrode 163 disposed on a substrate 110, the plurality of light-emitting elements 10 disposed on the plurality of first electrodes 161, a first optical layer 141 disposed between the plurality of light-emitting elements 10, and the second electrode 170 disposed on the plurality of light-emitting elements 10.

The substrate 110 may include plastic having flexibility. For example, the substrate 110 may be fabricated as a single-layer or multi-layer substrate including a material selected from polyimide, polyethylene terephthalate, polyethylene naphthalate, polycarbonate, polyethersulfone, polyarylate, polysulfone, and a cyclic-olefin copolymer, but is not limited thereto. For example, the substrate 110 may be a ceramic substrate or glass substrate.

A pixel driving circuit 20 may be disposed in the display region AA on the substrate 110. The pixel driving circuit 20 may include a plurality of thin film transistors using an amorphous silicon semiconductor, a polycrystalline silicon semiconductor, or an oxide semiconductor.

The pixel driving circuit 20 may include at least one driving thin film transistor, at least one switching thin film transistor, and at least one storage capacitor. The pixel driving circuit 20 may be formed on the substrate 110 through a process of fabricating a thin film transistor (TFT) when including a plurality of thin film transistors. In the embodiment, the pixel driving circuit 20 may be a concept that collectively refers to a plurality of thin film transistors electrically connected to the light-emitting elements 10.

The pixel driving circuit 20 may be a driving driver fabricated on a single crystal semiconductor substrate 110 using a process of fabricating a metal-oxide-silicon field effect transistor (MOSFET). The driving driver may include a plurality of pixel driving circuits to drive a plurality of sub-pixels. When the pixel driving circuit 20 is implemented as a driving driver, after an adhesive layer is disposed on the substrate 110, the driving driver may be mounted on the adhesive layer through a transfer process.

A buffer layer 121 which covers the pixel driving circuit 20 may be disposed on the substrate 110. The buffer layer 121 may include an organic insulating material, for example, photosensitive photo acryl or photosensitive polyimide, but is not limited thereto.

The buffer layer 121 may be formed by stacking an inorganic insulating material, for example, silicon nitride (SiNₓ), silicon oxide (SiO₂), or the like in a multi-layer manner, or by stacking an organic insulating material and an inorganic insulating material in a multi-layer manner.

An insulating layer 122 may be disposed on the buffer layer 121. The insulating layer 122 may include an organic insulating material, for example, photosensitive photo acryl or photosensitive polyimide, but is not limited thereto. Connection lines RT1 and RT2 may be disposed on the buffer layer 121. The connection lines may include a plurality of connection lines such as a first connection line RT1, a second connection line RT2, and the like. The connection lines RT1 and RT2 may be connected to the corresponding signal lines TL1 to TL6. The signal lines may include the first signal line TL1 to the sixth signal line TL6, but are not limited thereto. The connection lines RT1 and RT2 may include a plurality of line patterns disposed on different layers with one or more insulating layers interposed therebetween. The line patterns disposed on different layers may be electrically connected through contact holes passing through the insulating layer.

A plurality of bank patterns 130 may be disposed on the insulating layer 122. At least one light-emitting element 10 may be disposed on each bank pattern 130. For example, a first light-emitting element 11 may be disposed on a first bank pattern 130a, a second light-emitting element 12 may be disposed on a second bank pattern 130b, and a third light-emitting element 13 may be disposed on a third bank pattern 130c.

The bank pattern 130 may include an organic insulating material, for example, photosensitive photo acryl or photosensitive polyimide, but is not limited thereto. The bank pattern 130 may guide a position where the light-emitting elements 10 will be attached in the transfer process of the light-emitting elements 10. The bank pattern 130 may also be omitted.

A solder pattern 162 may be disposed on the first electrode 161. The solder pattern 162 may include indium (In), tin (Sn), or an alloy thereof, but is not limited thereto.

Each of the plurality of light-emitting elements 10 may be mounted on the solder pattern 162. One pixel may include light-emitting elements 10 of three colors. The first light-emitting element 11 may be a red light-emitting element, the second light-emitting element 12 may be a green light-emitting element, and the third light-emitting element 13 may be a blue light-emitting element. Two light-emitting elements may be mounted in each sub-pixel.

The first optical layer 141 may cover the plurality of light-emitting elements 10 and the bank patterns 130. Accordingly, the first optical layer 141 may cover a space between the plurality of light-emitting elements 10 and a space between the plurality of bank patterns 130. The first optical layers 141 may be disposed to extend in the first direction (e.g., X-axis direction) and spaced apart in the second direction (e.g., Y-axis direction) to separate pixels in the second direction. Accordingly, the first optical layers 141 may be separated between pixel rows. Here, a row may mean the first direction. Further, one pixel row composed of a plurality of pixels disposed in the first direction may be referred to as a pixel group. Accordingly, the display panel may include a plurality of pixel groups disposed to be spaced apart from each other in the second direction. For example, since the first optical layer 141 disposed in the first direction is disposed around the pixels, and the plurality of first optical layers 141 disposed corresponding to the plurality of pixel groups are disposed to be spaced apart from each other in the second direction, one first optical layer 141 disposed around the pixels forming one row may be separated from another first optical layer 141 disposed around the pixels forming another row.

The first optical layer 141 may include an organic insulating material in which fine metal particles such as titanium dioxide particles are dispersed. Light emitted from the plurality of light-emitting elements 10 may be scattered by the fine metal particles dispersed in the first optical layer 141 and emitted to the outside.

The second electrode 170 may be disposed on the plurality of light-emitting elements 10. The second electrode 170 may be connected to the plurality of pixels PXL in common. The second electrode 170 may be a thin electrode which transmits light. The second electrode 170 may be a transparent electrode material, for example, indium tin oxide (ITO), but is not necessarily limited thereto.

The second electrode 170 may extend in the first direction (the X-axis direction) and may be spaced apart in the second direction (the Y-axis direction). For example, one second electrode 170 may be formed to extend in the first direction, and a plurality of second electrodes 170 extending in the first direction may be spaced apart from each other in the second direction. In this case, the second electrodes 170 may be disposed corresponding to the pixels spaced apart from each other in the second direction, respectively. The second electrode 170 may include a first region 171 disposed on an upper surface of the light-emitting element 10 and an upper surface of the first optical layer 141, a second region 172 which is in contact with the contact electrode 163 and electrically connected to the contact electrode 163, and a third region 173 which is disposed on a side surface of the first optical layer 141 and connects the first region 171 and the second region 172.

Each of the plurality of second electrodes 170 may overlap the first optical layer 141 on a plane, and the third region 173 may cover an outer plane of the first optical layer 141.

A second optical layer 142 may be an organic insulating material surrounding the first optical layer 141. The second optical layer 142 may be disposed on the insulating layer 122 along with the first optical layer 141. The first optical layer 141 and the second optical layer 142 may include the same material (for example, siloxane). For example, the first optical layer 141 may be a siloxane containing titanium oxide (TiOₓ), and the second optical layer 142 may be a siloxane not containing titanium oxide (TiOₓ). However, the present disclosure is not necessarily limited thereto, and the first optical layer 141 and the second optical layer 142 may be formed of the same material or may be formed of different materials.

According to the embodiment, since the second region 172 of the second electrode 170 is connected to the contact electrode 163 in an overall flat state, excessive stress is not concentrated at a point connected to the contact electrode 163. Accordingly, cracks may be effectively prevented from occurring in the second electrode 170.

The second optical layer 142 may cover the second region 172 and the third region 173 of the second electrode 170. An upper surface of the second optical layer 142 and an upper surface of the first region 171 of the second electrode 170 may form the same plane. That is, the first region 171 and the second optical layer 142 may function as a planarization layer. Accordingly, since there is no step on a surface where a black matrix 190 is formed, a pattern of the black matrix 190 may be easily formed on the first optical layer 141 and the second optical layer 142. However, the present disclosure is not necessarily limited thereto, and the upper surfaces of the second optical layer 142 and the second electrode 170 may have different heights.

The black matrix 190 may be an organic insulating material to which a black pigment is added. The second electrode 170 may be in contact with the contact electrode 163 under the black matrix 190. Transmission holes 191 through which light emitted from the light-emitting elements 10 is emitted to the outside may be formed between the patterns of the black matrix 190. The transmission holes 191 may overlap the light-emitting elements 10 in the Z-axis direction, and a portion of the black matrix 190 may overlap the first optical layer 141 in the Z-axis direction. Here, the Z-axis direction may be referred to as the third direction. The black matrix 190 may improve the problem in which light from each of the neighboring light-emitting elements 10 is mixed by the first optical layer 141 and then emitted.

A cover layer 180 may be an organic insulating material which covers the black matrix 190 and the second electrode 170. In FIGS. 2 and 3, the configurations of the black matrix 190 and the cover layer 180 are omitted.

The contact electrode 163 is electrically connected to the first connection line RT1 disposed thereunder, and the first connection line RT1 may be connected to the pixel driving circuit 20. Accordingly, the cathode voltage may be applied to the second electrode 170 through the contact electrode 163. The first electrode 161 may be electrically connected to the second connection line RT2. This will be described below.

Referring to FIG. 5, the contact electrode 163 and the signal lines TL1 to TL6 may be disposed on the same plane. The pixel driving circuit 20 may be disposed under the contact electrode 163 and the signal lines TL1 to TL6. When the pixel driving circuit 20 is a driving driver, a plurality of driving drivers may be disposed in the display panel.

A passivation layer 133 may expose the contact electrode 163 so that the contact electrode 163 and the second electrode 170 are electrically connected. Further, the passivation layer 133 may insulate the signal lines TL2 to TL5 and the second electrode 170. Here, the passivation layer 133 may be formed of an inorganic material.

Referring to FIG. 6, the first electrode 161 may extend to one side surface 131 of the bank pattern 130 through the connection portion 161a and may be electrically connected to the second connection line RT2 disposed on the insulating layer 122.

The first electrode 161, the connection portion 161a, the signal lines TL, and/or the connection lines RT1 and RT2 may include a single layer or multi-layer metal layer selected from titanium (Ti), molybdenum (Mo), and aluminum (Al).

The first electrode 161 or the signal lines TL may be formed to have a metal stack structure in which a plurality of metal layers is formed using metal materials having different materials, thicknesses, and the like. In this case, the first electrode 161, the connection portion 161a, and the signal lines TL may be formed simultaneously through the same fabrication process. Here, the thickness may mean a width between one side and the other side of the metal layer disposed in the Z direction.

The first electrode 161 may include a first metal layer ML1 disposed under the solder pattern 162, a second metal layer ML2 disposed under the first metal layer ML1, a third metal layer ML3 disposed under the second metal layer ML2, and a fourth metal layer ML4 disposed under the third metal layer ML3. When the first electrode 161 is formed of the first metal layer ML1, the second metal layer ML2, the third metal layer ML3, and the fourth metal layer ML4, the first electrode 161 may be deposited in the order of the fourth metal layer ML4->the third metal layer ML3->the second metal layer ML2->the first metal layer ML1, and then patterned by performing a photolithography process and an etching process.

The first metal layer ML1 may be disposed in contact with a lower portion of the solder pattern 162 and electrically connected to the solder pattern 162.

Further, the first metal layer ML1 may include a transparent conductive oxide layer such as indium tin oxide (ITO) or indium zinc oxide (IZO) which has an excellent adhesive strength and is corrosion and acid resistant. Here, the first metal layer ML1 may be referred to as an adhesive layer.

The second metal layer ML2 may be formed of a material having a different resistance value from the first metal layer ML1 and the third metal layer ML3. In this case, the second metal layer ML2 may be formed of a material having a lower light reflectivity but a higher resistance value than the third metal layer ML3. For example, the second metal layer ML2 may include titanium (Ti) or molybdenum (Mo).

The third metal layer ML3 may be formed of a material having a higher light reflectivity than the first metal layer ML1. In this case, the third metal layer ML3 may be formed of a material having a higher light reflectivity than the second metal layer ML2. For example, the third metal layer ML3 may include aluminum (Al) or silver (Ag).

The light reflectivity of the third metal layer ML3 may be higher than the light reflectivity of each of the first metal layer ML1 and the second metal layer ML2.

The fourth metal layer ML4 may be formed of the same material as the second metal layer ML2. For example, the fourth metal layer ML4 may include titanium (Ti) or molybdenum (Mo).

After forming the first metal layer ML1, a reflective opening OP may be formed in the first electrode 161. The reflective opening OP may be a region where only a portion of the third metal layer ML3 is exposed by removing the first metal layer ML1 and the second metal layer ML2. The reflective opening OP may have a form surrounding the solder pattern 162 on a plane, and have a circular shape or quadrangular shape, but is not limited thereto.

Light emitted from the light-emitting element 10 is reflected from a surface of the third metal layer ML3 exposed by the reflective opening OP, which may have an effect of increasing the light efficiency of the display device.

The passivation layer 133 may be disposed on the first electrode 161 and the signal line TL and may include an opening hole 133a which exposes the solder pattern 162. Here, the opening hole 133a which exposes the solder pattern 162 may be referred to as a first opening hole. In this case, the reflective opening OP may be formed to surround the first opening hole.

The light-emitting element 10 may include a first conductivity-type semiconductor layer 10-1, an active layer 10-2 disposed on the first conductivity-type semiconductor layer 10-1, and a second conductivity-type semiconductor layer 10-3 disposed on the active layer 10-2. A first driving electrode 15 may be disposed under the first conductivity-type semiconductor layer 10-1, and a second driving electrode 14 may be disposed on the second conductivity-type semiconductor layer 10-3.

The light-emitting element 10 may be formed on a silicon wafer using a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), sputtering, or the like.

The first conductivity-type semiconductor layer 10-1 may be implemented with a compound semiconductor of group III-V, group II-VI, or the like and may be doped with a first dopant. The first conductivity-type semiconductor layer 10-1 may be formed of any one or more selected from semiconductor materials having a composition formula of Alₓ₁In_{y1}Ga_{(1-x1-y1)}N (0≤x1≤1, 0≤y1≤1, and 0≤x1+y1≤1), InAlGaN, AlGaAs, GaP, GaAs, GaAsP, and AlGaInP, but is not limited thereto. When the first dopant is an n-type dopant such as Si, Ge, Sn, Se, Te, or the like, the first conductivity-type semiconductor layer 10-1 may be an n-type nitride semiconductor layer. However, when the first dopant is a p-type dopant, the first conductivity-type semiconductor layer 10-1 may be a p-type nitride semiconductor layer.

The active layer 10-2 is a layer in which electrons (or holes) injected through the first conductivity-type semiconductor layer 10-1 and holes (or electrons) injected through the second conductivity-type semiconductor layer 10-3 meet. As the electrons and the holes recombine, the active layer 10-2 transitions to a lower energy level, and may generate light having a wavelength corresponding thereto.

The active layer 10-2 may have any one structure among a single well structure, a multiple well structure, a single quantum well structure, a multi quantum well (MQW) structure, a quantum dot structure, and a quantum line structure, but the structure of the active layer 10-2 is not limited thereto. The active layer 10-2 may generate light in the visible light wavelength band. For example, the active layer 10-2 may output light in any one of the blue, green, and red wavelength bands.

The second conductivity-type semiconductor layer 10-3 may be disposed on the active layer 10-2. The second conductivity-type semiconductor layer 10-3 may be implemented with a compound semiconductor of group III-V, group II-VI, or the like, and may be doped with a second dopant. The second conductivity-type semiconductor layer 10-3 may be formed of any one or more selected from semiconductor materials having a composition formula of Inₓ₂Al_{y2}Ga_{1-x2-y2}N (0≤x2≤1, 0≤y2≤1, and 0≤x2+y2≤1), AlInN, AlGaAs, GaP, GaAs, GaAsP, and AlGaInP, but is not limited thereto. When the second dopant is a p-type dopant such as Mg, Zn, Ca, Sr, Ba, or the like, the second conductivity-type semiconductor layer 10-3 doped with the second dopant may be a p-type semiconductor layer. However, when the second dopant is an n-type dopant, the second conductivity-type semiconductor layer 10-3 may be an n-type nitride semiconductor layer.

In the embodiment, although a vertical structure in which the driving electrodes 14 and 15 are disposed at the top and bottom of a light-emitting structure is described, the light-emitting element may have a lateral structure or flip chip structure in addition to the vertical structure.

Referring to FIG. 7, a main light-emitting element 12a and a sub light-emitting element 12b of the sub-pixel may be disposed on the bank pattern 130. The second light-emitting element 12 will be described as an example. A 1-1 electrode 161-1 connected to the main light-emitting element 12a may extend to one side surface of the bank pattern 130 and may be electrically connected to a 2-1 connection line RT21 disposed thereunder. A 1-2 electrode 161-2 connected to the sub light-emitting element 12b may extend to the other side surface of the bank pattern 130 and may be electrically connected to a 2-2 connection line RT22 disposed thereunder.

The pixel driving circuit 20 may apply an anode voltage to the main light-emitting element 12a through the 2-1 connection line RT21, and apply an anode voltage to the sub light-emitting element 12b through the 2-2 connection line RT22. The pixel driving circuit 20 may apply a cathode voltage to the main light-emitting element 12a and the sub light-emitting element 12b through the first connection line RT1 and the second electrode 170.

The pixel driving circuit 20 may adjust brightness by driving only the main light-emitting element 12a, and may also adjust brightness by simultaneously driving the main light-emitting element 12a and the sub light-emitting element 12b. When the main light-emitting element 12a is darkened, the brightness may be adjusted by driving only the sub light-emitting element 12b.

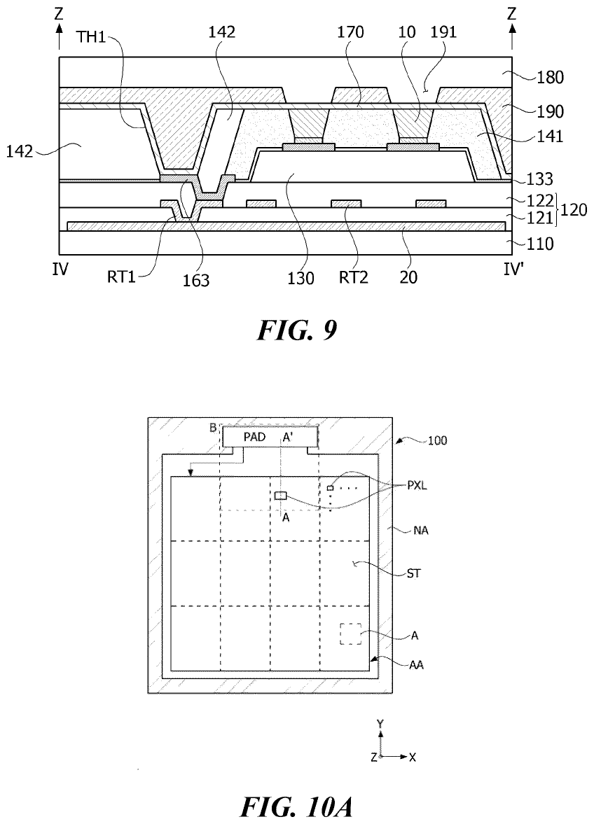

FIG. 8 is a view illustrating a display device according to another embodiment of the present disclosure. FIG. 9 is a cross-sectional view taken along line IV-IV′ in FIG. 8.

Referring to FIGS. 8 and 9, a second electrode 170 may be electrically connected to a contact electrode 163 through a contact hole TH1 formed in a second optical layer 142. The second optical layer 142 may include the contact hole TH1 which exposes the contact electrode 163. The second electrode 170 inserted into the contact hole TH1 of the second optical layer 142 may be in contact with an upper surface of the contact electrode 163. The contact hole TH1 may be formed in an outer region of a pixel.

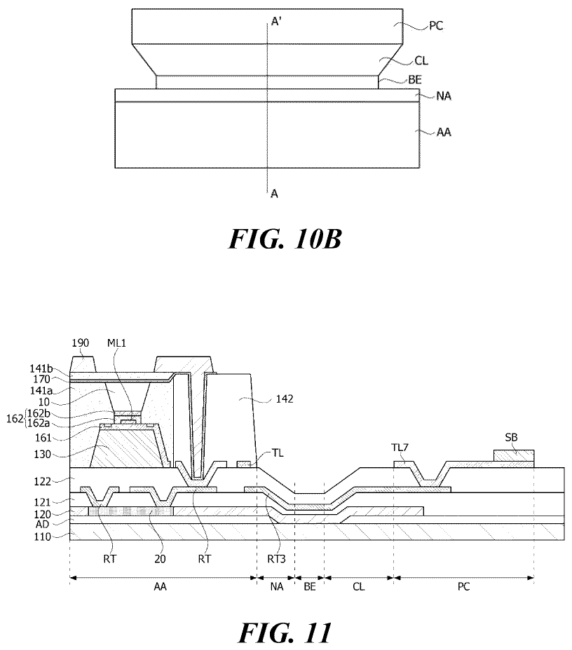

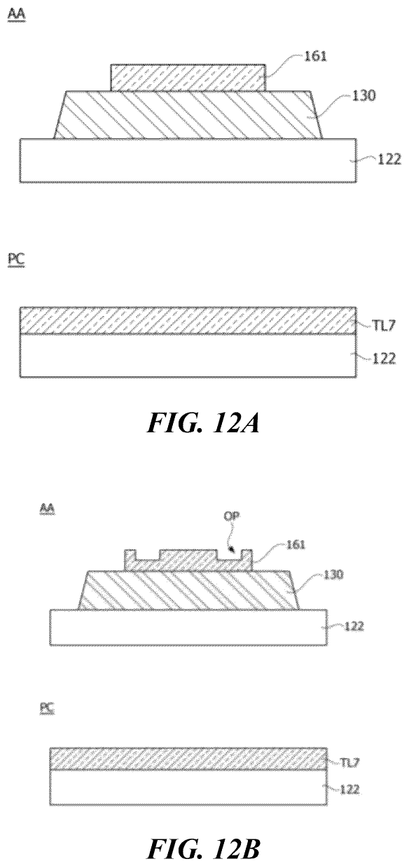

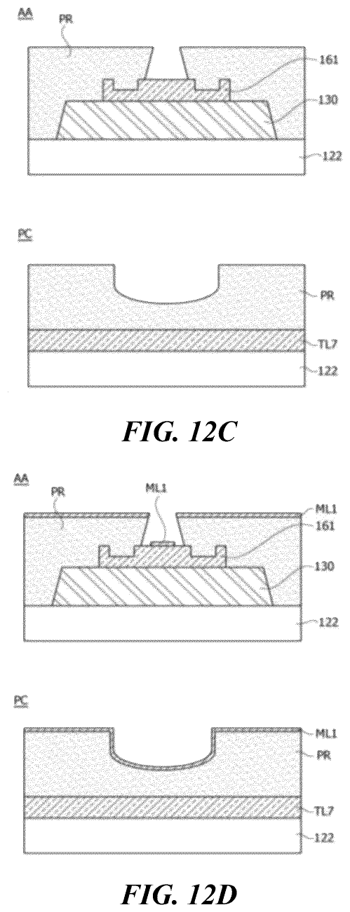

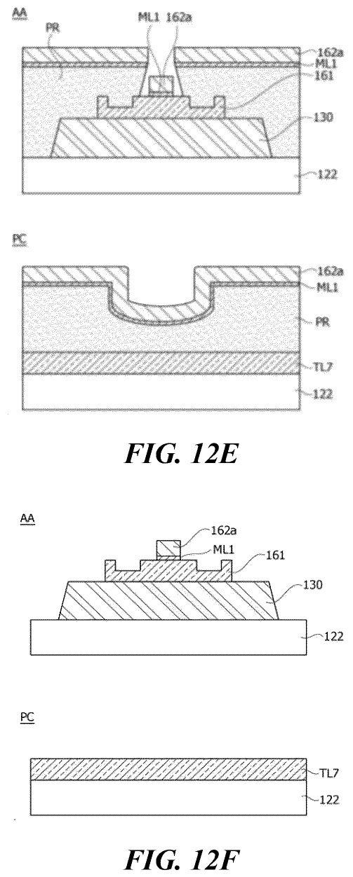

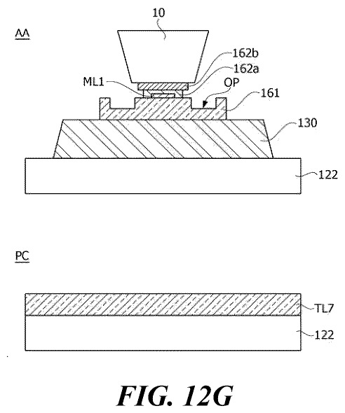

FIG. 10A is a view illustrating a display device according to another embodiment of the present disclosure. FIG. 10B is an enlarged view of region B in FIG. 10A. FIG. 11 is a cross-sectional view taken along line A-A′ in FIG. 10B. FIGS. 12A to 12G are views illustrating a process of fabricating a display device according to one embodiment of the present disclosure.

Hereinafter, since the content for configurations the same as the configurations included in the embodiment described in FIGS. 1 to 9 is redundant and will be omitted, the description will focus on other features.

Referring to FIGS. 10A and 10B, a display panel may include a display region AA where an image is displayed and a non-display region NA where the image is not displayed. In the non-display region NA, various lines and driving circuits may be mounted, and a pad portion PC to which an integrated circuit, a printed circuit, and the like are connected may be disposed. A bending region BE and a connection line region CL may be disposed between the non-display region NA and the pad portion PC.

In the non-display region NA, data driving circuits or gate driving circuits may be disposed, and lines supplying control signals for controlling these driving circuits may be disposed. Here, the control signal may include various timing signals including a clock signal, an input data enable signal, and a synchronization signal and may be received from the pad portion PC through lines disposed in the connection line region CL.

Referring to FIG. 11, the display device according to another embodiment includes a plurality of first electrodes 161 and a contact electrode 163 disposed on a substrate 110, a plurality of light-emitting elements 10 disposed on the plurality of first electrodes 161, a first optical layer 141 disposed between the plurality of light-emitting elements 10, and a second electrode 170 disposed on the plurality of light-emitting elements 10.

An adhesive layer AD may be disposed on the substrate 110. A region where the adhesive layer AD is removed may be present in the non-display region NA or bending region BE. This is because the more organic layers there are in the bending region BE, the higher the risk of an organic layer being damaged or broken in the bending region BE. The adhesive layer AD may be selected from, for example, any one of an adhesive polymer, epoxy resin, ultraviolet (UV) resin, polyimide series, acrylate series, urethane series, and polydimethylsiloxane (PDMS), but is not limited thereto.

A pixel driving circuit 20 implemented as a driving driver may be disposed on the adhesive layer AD in the display region AA.

A protective layer 120 may be formed on the adhesive layer AD to protect the pixel driving circuit 20. The protective layer 120 may cover at least a portion or all of a side surface of the pixel driving circuit 20 and cover a portion of an upper surface of the pixel driving circuit 20. The protective layer 120 may cover the entire substrate 110 and cover a portion of the pad portion PC. The protective layer 120 may include an organic insulating material, for example, photosensitive photo acryl or photosensitive polyimide, but is not limited thereto.

A buffer layer 121 which covers the pixel driving circuit 20 may be disposed on the protective layer 120. When the protective layer 120 covers only the portion of the pad portion PC, a side surface of the protective layer 120 may be covered by the buffer layer 121.

An insulating layer 122 may be disposed on the buffer layer 121. Connection lines RT may be disposed on the buffer layer 121. The connection lines RT may be connected to the corresponding signal lines TL. The connection lines RT1 and RT2 may include a plurality of line patterns disposed on different layers with one or more insulating layers interposed therebetween. The line patterns disposed on different layers may be electrically connected through contact holes passing through the insulating layer. A third connection line RT3 may be disposed on the buffer layer 121, and a signal from the pad portion PC may be transmitted to the display region AA through the third connection line RT3. The signal transmitted through the third connection line RT3 may be supplied to the pixel driving circuit 20 through the connection lines RT and the signal lines TL.

A plurality of bank patterns 130 may be disposed on the insulating layer 122. At least one light-emitting element 10 may be disposed on each bank pattern 130. For example, referring to FIG. 3, a first light-emitting element 11 may be disposed on a first bank pattern 130a, a second light-emitting element 12 may be disposed on a second bank pattern 130b, and a third light-emitting element 13 may be disposed on a third bank pattern 130c.

The first electrode 161 may be disposed on the bank pattern 130. In the embodiment, the first electrode 161 may include a plurality of metal layers ML2, ML3, and ML4 except for a first metal layer ML1 in a formation process, and in a separate process, the first metal layer ML1 may be disposed only in a region overlapping the first electrode 161 and the light-emitting element 10. An opening OP may be disposed in the first electrode 161. In the embodiment, the opening OP may be formed by removing the second metal layer ML2. The first metal layer ML1 may not be disposed on the pad portion PC. Further, the first metal layer ML1 may not be disposed in regions except for the region overlapping the light-emitting element 10.

A solder pattern 162 may be disposed on the first electrode 161. The solder pattern 162 may include indium (In), tin (Sn), or an alloy thereof, but is not limited thereto. The solder pattern 162 may include a first portion 162a and a second portion 162b. The first portion 162a may include indium (In), and the second portion 162b may include gold (Au). When the light-emitting element 10 is transferred, the first portion 162a and the second portion 162b may be bonded by pressure and then eutectically bonded by applying heat. When the second portion 162b receives pressure, a portion of the second portion 162b may cover at least a portion or all of a side surface of the first portion 162a. In this case, since a contact area between the first portion 162a and the second portion 162b increases, an adhesive strength may increase and electrical signal transmission may be improved.

The plurality of light-emitting elements 10 may each be mounted on the solder pattern 162.

A 1-1 optical layer 141a may cover the plurality of light-emitting elements 10 and the bank patterns 130. Accordingly, the 1-1 optical layer 141a may cover a space between the plurality of light-emitting elements 10 and a space between the plurality of bank patterns 130. Disposition of the 1-1 optical layer 141a on a plane is the same as disposition of the first optical layer 141 on a plane.

The second electrode 170 may be disposed on the plurality of light-emitting elements 10. The second electrode 170 may be connected to the plurality of pixels PXL in common.

The 1-2 optical layer 141b may be disposed to overlap the 1-1 optical layer 141a on the second electrode 170. The 1-2 optical layer 141b may be disposed on the second electrode 170 to increase the amount of light emitted to the front.

The second optical layer 142 may be an organic insulating material surrounding the first optical layer 141. The second optical layer 142 may be disposed on the insulating layer 122 along with the first optical layer 141. The second optical layer 142 may be disposed on the display region AA.

A black matrix 190 may be disposed on the 1-2 optical layer 141b, the second electrode 170, and the second optical layer 142. Transmission holes through which light emitted from the light-emitting elements 10 is emitted to the outside may be formed between patterns of the black matrix 190.

A cover layer 180 may be an organic insulating material which covers the black matrix 190 and the second electrode 170. In FIG. 11, the configurations of the cover layer 180 are omitted.

A circuit component SB may be disposed on a seventh signal line TL7 in the pad portion PC. The circuit component SB may be attached to the pad portion PC in the form of a chip on panel (COP) or chip on film (COF).

As described above, the first metal layer ML1 may be formed only in a region overlapping the light-emitting element 10. When the first metal layer ML1 includes indium tin oxide (ITO), since an adhesive strength with the 1-1 optical layer 141a and/or the second optical layer 142 is reduced, a lifting phenomenon of the 1-1 optical layer 141a and/or the second optical layer 142 on the first metal layer ML1 may occur.

Further, in the pad portion PC, when the circuit component SB is attached to the seventh signal line TL7 through an adhesive containing conductive balls such as an anisotropic conductive film (ACF), a problem in that contact resistance with the first metal layer ML1 increases may occur.

In addition, when wet etching is performed to form the opening OP in the first metal layer ML1 including indium tin oxide (ITO) disposed on the bank pattern 130, a problem in that crystallized indium tin oxide (ITO) is not etched may occur. In order to prevent this problem, the first metal layer ML1 may be formed only in the region overlapping the light-emitting element 10.

FIGS. 12A to 12G are views illustrating the process of fabricating the display device according to one embodiment of the present disclosure shown in FIG. 11. FIGS. 12A to 12G are drawings for describing the process, and components unnecessary for description such as a detailed electrode connection structure, the substrate 110, and the like have been omitted. Each drawing illustrates a cross-sectional view of the display device in the display region AA and the pad portion PC. The non-display region NA has the same fabrication process as the pad portion (PC).

Referring to FIG. 12A, the first electrode 161 is formed on the bank pattern 130 formed on the insulating layer 122 in the display region AA. The seventh signal line TL7 is formed on the insulating layer 122 in the pad portion PC. The first electrode 161 and the seventh signal line TL7 may be formed in the same process and may include a plurality of metal layers ML2, ML3, and ML4 except for the first metal layer ML1.

Referring to FIG. 12B, the opening OP is formed by removing the second metal layer ML2 included in the first electrode 161 in the display region AA using an etching process.

Referring to FIGS. 12C and 12D, photoresist PR is applied to an entire surface of the substrate 110. Further, the photoresist PR located in a region where the first metal layer ML1 of the display region AA will be formed and a partial region of the pad portion PC is patterned. Specifically, when exposure is performed with a difference in hardening degrees of the surface and inside in a photolithography process, an anisotropic shape may be made after development.

A patterned region of the photoresist PR applied to the display region AA may have a reverse step. A patterned region of the photoresist PR applied to the pad portion PC may have a round or concave shape. Thereafter, a metal layer having the same component as the first metal layer ML1 is disposed on the entire surface of the patterned region. A portion of the metal layer having the same component as the first metal layer ML1 (that is, a first metal forming layer) is disposed on the first electrode 161 in the region where the photoresist PR is patterned in the display region AA, and is referred to as the first metal layer ML1. In the pad portion PC, the first metal layer ML1 is disposed on an entire surface of the pad portion PC.

Referring to FIG. 12E, a metal layer having the same component as the first portion 162a of the solder pattern (that is, a solder pattern forming layer) is disposed in the display region AA and the pad portion PC. The first portion 162a of the solder pattern may be disposed on the first metal layer ML1 in the region where the photoresist PR is patterned in the display region AA.

Referring to FIG. 12F, when the photoresist PR applied on the substrate 110 is removed through a lift-off process, the metal layer having the same composition as the first metal layer ML1 disposed on the photoresist PR and the metal layer having the same composition as the first portion 162a of the solder pattern may be removed along with the photoresist PR.

Referring to FIG. 12G, the light-emitting element 10 is transferred to the first portion 162a of the solder pattern. The second portion 162b of the solder pattern may be disposed under the light-emitting element 10. When the light-emitting element 10 is transferred, a pressure is applied, and in this case, the first portion 162a may be compressed by the pressure and cover at least a portion of a side surface of the first metal layer ML1. According to one embodiment of the present disclosure shown in FIGS. 12A to 12G, the first metal layer ML1 may disposed on the first electrode 161 in a region overlapping the light-emitting element 10, and may not be disposed in the remaining region. The manufacturing process of the display device according to an embodiment of the present discloses further sequentially comprises; disposing a 1-1 optical layer 141a surrounding the light-emitting element 10; disposing a second electrode 170 on the light-emitting element 10 and the 1-1 optical layer 141a; and disposing a 1-2 optical layer 141b on the second electrode 170, which are not shown in FIGS. 12A to 12G.

In the embodiment, although a vertical structure in which the driving electrodes 14 and 15 are disposed at the top and bottom of the light-emitting structure is described, the light-emitting element may have a lateral structure or flip chip structure in addition to the vertical structure.

The display device according to the embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation system, a vehicle display device, a theater display device, a television, a wallpaper device, a signage device, a game device, a laptop computer, a monitor, a camera, a camcorder, a home appliance, etc. In addition, the display device according to one or more embodiments of the present disclosure may be applied to an organic light emitting lighting device or an inorganic light emitting lighting device.

The display device according to various embodiments of the present disclosure may be described as follows.

A display device according to one embodiment of the present disclosure may comprise an insulating layer disposed on a substrate; a bank pattern disposed on the insulating layer; a first electrode including a plurality of metal layers disposed on the bank pattern; a first metal layer disposed on the first electrode; a solder pattern disposed on the first metal layer; a light-emitting element disposed on the solder pattern; and a second electrode disposed on the light-emitting element, wherein the first metal layer is disposed only in a region overlapping the light-emitting element.

A display device according to one embodiment of the present disclosure may further include a first optical layer surrounding the light-emitting element.

According to a display device of one embodiment of the present disclosure, the plurality of metal layers included in the first electrode may include a second metal layer, a third metal layer, and a fourth metal layer sequentially.

According to a display device of one embodiment of the present disclosure, the solder pattern may include a first portion disposed on the first metal layer and a second portion disposed on the first portion; wherein the first portion covers a side surface of the first metal layer; and wherein the first portion includes indium, and the second portion includes gold.

A display device of one embodiment of the present disclosure may further include a second optical layer disposed on the second electrode, wherein the second optical layer has the same component as the first optical layer.

A display device of one embodiment of the present disclosure may further include an adhesive layer disposed between the substrate and the insulating layer; a pixel driving circuit disposed on the adhesive layer; a buffer layer disposed on the pixel driving circuit; and a plurality of connection lines disposed between the buffer layer and the insulating layer, wherein the pixel driving circuit is connected to the plurality of connection lines, and the plurality of connection lines are electrically connected to the first electrode.

According to a display device of one embodiment of the present disclosure, openings may be formed in the first electrode at a position not overlapped with the first metal layer.

According to a display device of one embodiment of the present disclosure, the openings may be disposed to surround the solder pattern.

According to a display device of one embodiment of the present disclosure, the first metal layer may include indium tin oxide or indium zinc oxide.

A method of fabricating display device of one embodiment of the present disclosure may comprise disposing an insulating layer on a substrate; disposing a bank pattern on the insulating layer in the display area; disposing a first electrode including a plurality of metal layers on the bank pattern; forming openings in the first electrode; disposing a first metal layer on the first electrode between the openings; disposing a solder pattern on the first metal layer; disposing a light-emitting element overlapping the first metal layer on the solder pattern; and disposing a second electrode on the light-emitting element.

A method of fabricating display device of one embodiment of the present disclosure before disposing the second electrode on the light-emitting element, may further include disposing a first optical layer surrounding the light-emitting element.

A method of fabricating display device of one embodiment of the present disclosure after disposing the second electrode on the light-emitting element, may further include disposing a second optical layer on the second electrode.

According to a method of fabricating display device of one embodiment of the present disclosure, the plurality of metal layers may include a second metal layer, a third metal layer, and a fourth metal layer.

According to a method of fabricating display device of one embodiment of the present disclosure, the disposing of the first metal layer may include a process of forming a photoresist on the insulating layer, the first electrode and the bank pattern; a process of patterning the photoresist to expose a portion where the first metal layer is formed among the first electrode; a process of sequentially forming a first metal forming layer and a solder pattern forming layer on the photoresist and the first electrode; and a process of performing a lift off process to remove the first metal forming layer and the solder pattern forming layer on the photoresist along with the photoresist, wherein the first metal forming layer on the first electrode is the first metal layer.

According to a method of fabricating display device of one embodiment of the present disclosure, the openings may be formed in the first electrode at a position not overlapped with the first metal layer.

According to a method of fabricating display device of one embodiment of the present disclosure, the openings may be formed to surround the solder pattern.

The effects of the present disclosure are not limited to the above-described effects, and other effects that are not mentioned will be able to be clearly understood by those skilled in the art from the above detailed description.

Although embodiments of the present disclosure have been described in more detail with reference to the accompanying drawings, the present disclosure is not necessarily limited to the embodiments, and various modifications may be carried out without departing from the technical spirit of the present disclosure. Therefore, the embodiments disclosed in the present disclosure are not intended to limit the technical spirit of the present disclosure, but intended to describe the same, and the scope of the technical spirit of the present disclosure is not limited by these embodiments. Therefore, it should be understood that the above-described embodiments are illustrative and not restrictive in all respects.

The various embodiments described above can be combined to provide further embodiments. All of the U.S. patents, U.S. patent application publications, U.S. patent applications, foreign patents, foreign patent applications and non-patent publications referred to in this disclosure and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the disclosure and the claims, but should be construed to include all possible embodiments along with the full scope of equivalents to which such claims are entitled. Accordingly, the claims are not limited by the disclosure.

1. A display device comprising:
an insulating layer disposed on a substrate;
a bank pattern disposed on the insulating layer;
a first electrode including a plurality of metal layers disposed on the bank pattern;
a first metal layer disposed on the first electrode;
a solder pattern disposed on the first metal layer;
a light-emitting element disposed on the solder pattern; and
a second electrode disposed on the light-emitting element,
wherein the first metal layer overlaps the light-emitting element from a plan view.

2. The display device of claim 1, further comprising a first optical layer surrounding the light-emitting element.

3. The display device of claim 1, wherein the plurality of metal layers included in the first electrode include a second metal layer, a third metal layer, and a fourth metal layer sequentially.

4. The display device of claim 1, wherein:
the solder pattern includes a first portion disposed on the first metal layer and a second portion disposed on the first portion;
wherein the first portion covers a side surface of the first metal layer, and
wherein the first portion includes indium, and the second portion includes gold.

5. The display device of claim 2, further comprising a second optical layer disposed on the second electrode,
wherein the second optical layer has a same component as the first optical layer.

6. The display device of claim 1, further comprising:
an adhesive layer disposed between the substrate and the insulating layer;
a pixel driving circuit disposed on the adhesive layer;
a buffer layer disposed on the pixel driving circuit; and
a plurality of connection lines disposed between the buffer layer and the insulating layer,
wherein the pixel driving circuit is electrically connected to the plurality of connection lines, and
wherein the plurality of connection lines is electrically connected to the first electrode.

7. The display device of claim 1, wherein openings are formed in the first electrode at a position not overlapped with the first metal layer.

8. The display device of claim 7, wherein the openings are disposed to surround the solder pattern.

9. The display device of claim 1, wherein the first metal layer includes indium tin oxide or indium zinc oxide.

10. A method of fabricating a display device, comprising:
disposing an insulating layer on a substrate;
disposing a bank pattern on the insulating layer in the display area;
disposing a first electrode including a plurality of metal layers on the bank pattern;
forming openings in the first electrode;
disposing a first metal layer on the first electrode between the openings;
disposing a solder pattern on the first metal layer;
disposing a light-emitting element overlapping the first metal layer on the solder pattern; and
disposing a second electrode on the light-emitting element.

11. The method of claim 10, before disposing the second electrode on the light-emitting element, further comprising disposing a first optical layer surrounding the light-emitting element.

12. The method of claim 11, after disposing the second electrode on the light-emitting element, further comprising disposing a second optical layer on the second electrode.

13. The method of claim 10, wherein the plurality of metal layers includes a second metal layer, a third metal layer, and a fourth metal layer.

14. The method of claim 10, wherein the disposing of the first metal layer,
a process of forming a photoresist on the insulating layer including the first electrode and the bank pattern;
a process of patterning the photoresist to expose a portion where the first metal layer is formed among the first electrode;
a process of sequentially forming a first metal forming layer and a solder pattern forming layer on the photoresist and the first electrode; and
a process of performing a lift off process to remove the first metal forming layer and the solder pattern forming layer on the photoresist along with the photoresist,
wherein the first metal forming layer on the first electrode is the first metal layer.

15. The method of claim 10, wherein the openings are formed in the first electrode at a position not overlapped with the first metal layer.

16. The method of claim 10, wherein the openings are formed to surround the solder pattern.

17. A display device comprising:
an insulating layer disposed on a substrate;
a bank pattern disposed on the insulating layer;
a first electrode including a plurality of metal layers disposed on the bank pattern;
a first metal layer disposed on the first electrode;
a solder pattern disposed on the first metal layer;
a light-emitting element disposed on the solder pattern; and
a second electrode disposed on the light-emitting element,
wherein the first metal layer is disposed only in a region overlapping the light-emitting element.

18. The display device of claim 17, further comprising a first optical layer surrounding the light-emitting element.

19. The display device of claim 17, wherein openings are formed in the first electrode under a side surface of the first metal layer.

20. The display device of claim 19, wherein the openings are disposed to surround the solder pattern.
